(19) United States
(12) Patent Application Publication
(10) Pub. No.: US 2007/0222437 A1
(43) Pub. Date: Sep. 27, 2007

(54) Device for Locating Metallic Objects and Methods for Adjusting Such a Device

(76) Inventor: Bjoern Haase, Stuttgart (DE)

Correspondence Address: MICHAEL J. STRIKER, 103 EAST NECK ROAD, HUNTINGTON, NY, 11743, US

(21) Appl. No.: 10/594,285

(22) PCT Filed: Jul. 25, 2005
(86) PCT No.: PCT/EP05/53614

§ 371 Date: Sep. 26, 2006

(30) Foreign Application Priority Data
Sep. 29, 2004 (DE) 102004047188.6

(51) Int. Cl. G01R 33/12

(52) U.S. Cl. 324/228

(57) ABSTRACT

The invention relates to a device for locating metallic objects, with at least one transmit coil (116) and at least one receive turn system (112, 114; 212, 214), which are inductively coupled to one another.

According to the invention, switching means (1, . . . , 8; 1′a, 2′a, 3′a, 1′b, 2′b, 3′b) are provided, which make it possible to vary the effective number of turns of the at least one receive turn system (112, 114; 212, 214).

The present invention also relates to a method for operating a device of this type, in particular a method with which the adjustment of a voltage U induced in a receive coil (112, 114; 212, 214) takes place by connecting an adjustment turn system (113, 115; 213′, 215′) to the turns (113, 115; 213, 215) of the receive turn system (112, 114; 212, 214).

The present invention relates to a device for locating metallic objects according to the preamble of Claim 1, and a method for adjusting a device of this type.

### RELATED ART

Currently, detectors for locating metallic objects hidden in construction materials typically operate using inductive methods. They are based on the fact that conductive and ferromagnetic materials influence the properties of an electromagnetic coil located nearby. The changes in the inductive properties caused by metallic objects are registered by a receiving circuit of a detector of this type. In this manner, metallic objects enclosed in a wall can be located using one or more coils guided over the wall.

A technical difficulty encountered in the detection of metallic objects is the fact that the magnitude of the effect of the objects to be located on the coil or coils of the detector system is very small. This applies mainly with regard for the influence by non-ferromagnetic objects, e.g., copper, which is a technically important material. As a result, the inductive effect of the coils on each other can be markedly greater than the induction in the receive coil generated by an enclosed object.

The detectors based on an inductive method therefore typically have a high offset, i.e., a high signal that can be tapped at the receive coil, and which can be measured even when the receiving circuit is not influenced by an external, metallic object. A high offset of this type makes it difficult to detect very small inductive changes that are caused by a metallic object that enters the vicinity of the detector. The related art makes known sensor systems for inductive sensors and detectors that enable compensation of the signal induced by the coils themselves.

The need to detect a very small change in inductivity on a very large offset signal also requires that components be used that have narrow tolerances and are therefore expensive. It also requires that extremely low-noise analogue electronics be used, which markedly increases the costs for a locating device of this type. When assembly or manufacturing tolerances are not met, or when individual components drift relative to each other, the result measured by a device of this type is inevitably corrupted.

Various approaches for handling these offset problems are made known in the related art; they all have the objective of reducing the sensor signal that exists when no metallic objects are present, and to thereby magnify the relative signal changes.

A multi-step approach is often employed, in which, e.g., in a first step, an assembly of sensor coils is used that is ideally capable of completely eliminating or compensating the signal offset. The compensation quality attainable in practical application often depends, e.g., on manufacturing tolerances, however, which means an additional method of high-acuity compensation, as it were, is often required to completely eliminate the signal offset.

The known methods for compensation of manufacturing and assembly tolerances for inductive sensors in a compensation system are based essentially on the fact that the fault voltages induced in the detector system are offset by correcting the geometry of the exciting magnetic field using an adjustment process, or by generating a correction voltage signal. An example of the compensation method mentioned initially is provided in EP 1092989, and an example of the second compensation method is provided in U.S. Pat. No. 5,729,143.

Publication U.S. Pat. No. 5,729,143 makes known a detector designed to suppress the offset of the measured signal described above to the greatest extent possible. To this end, the detector described in U.S. Pat. No. 5,729,143 includes a transmit coil with a transmitter, and a receive coil with a receiver. The transmit coil and the receive coil of the detector are coupled with each other such that they partially overlap each other. The transmit coil is supplied with an alternating current by the transmitter. This current-carrying transmit coil excites—via its inductive coupling with the receive coil—a first sub-flux in the excite coil, in the overlapping area of the two coils, and it excites a second sub-flux in the remaining area of the receive coil. The distance between the centers of the transmit coil and the receive coil can now be selected such that the two sub-fluxes, which have opposite signs, compensate each other. When this is the case, and when an external, metallic object is not located near the coil assembly, the current-carrying transmit coil therefore does not induce any current in the receive coil. As such, the receiver would not measure an offset signal in this ideal case, either. The field lines generated by the transmit coil are not disturbed until the coil assembly is moved close to a metallic object; a non-disappearing flux is now induced in the receive coil, and it generates a measurement signal in the receive coil, which is not influenced by an offset signal and can be evaluated by the receiver.

The relative distance between the centers of the transmit coil and the receiver coil is an extremely critical parameter. As such, it takes a great deal of effort to realize the absence of an induced voltage in the receiver coil—this absence being ideally assumed—in practical applications. It has been shown that adequate compensation of the flux components cannot be realized in actual series production.

For this reason, publication U.S. Pat. No. 5,729,143 provides an electronic circuit that subsequently achieves compensation in an electronic manner and therefore makes the sensor usable in practical application. The method described in U.S. Pat. No. 5,729,143 operates in a monofrequent manner. On the exciter side, a magnetic alternating field of a certain frequency f is generated, and the induced voltage components are evaluated in the detector turns with suitable analog and digital filters on a frequency-selective basis at this frequency f. The voltage U(f) induced in the detector turns by the magnetic incorrect compensation of the detector and exciter system at frequency f has a temperature-dependent amplitude and phase angle, which is also subjected to additional manufacturing tolerances. The method described in U.S. Pat. No. 5,729,143 is based on adding a correction voltage—analogous to the voltages induced in the detector windings-the amplitude and phase angle of which offset the fault voltage U(f) at working frequency f. To this end, a microprocessor generates a digital correction signal—the phase and amplitude of which are controlled—at frequency f. The amplitude and phase angle required for the compensation depends on the phase shift, which is caused by the components of the circuits in the excitation and detector branch. The required correction signal is therefore also subjected to a temperature drift, among other things. In order to also compensate the fault voltage U(f) when the working temperature changes, the microprocessor must track the phase angle and amplitude of the correction signal as a function of temperature. To this end, it is usually necessary for the user to perform recalibration.

An alternative method for compensating a magnetic incorrect compensation is made known in EP 1092989 A1. With this method, corrective magnetic fields are used, instead of adding a correction voltage to the detection voltage induced in the detector turns. To this end, the system of magnetic field excitation is composed of the primary excitation coil and additional trim turns and “correction turns”. The difference between a trim turn and a correction turn is that the correction turns are connected in series with the primary excitation coil and therefore always carry the same current, while trim turns can carry an adjustable fraction of the current flowing in the correction and excitation coils. In this manner, it is possible to ensure that induced voltage does not occur in the detector coils when there are no metallic objects located near the sensor. The method described in publication EP 1092989 A1 depends much less on component tolerances and drifts in the transmit and receive circuits. Moreover, the measurement is not limited to a selected working frequency, since the compensation is largely independent of the frequency used. In comparison, the design of a sensor according to EP 1092989 A1 becomes much more complex. While the sensor described in U.S. Pat. No. 5,729,143 functions with only one coil each for the transit and receive circuits, the design described in EP 1022989 A1 requires ten coils in the excitation path and four coils for the detector path.

Publication DE 101 22 741 A1 makes known a detector for locating metallic objects, which includes a receive coil and a first transmit coil, which are inductively coupled with each other. To ensure that the smallest possible offset signal occurs in the detector, a second transmit coil is provided, which is also inductively coupled with the receive coil. The receive coil and the two transmit coils are located concentrically on a common axis. In terms of the number of turns and/or their dimensions, the two transmit coils are sized such that fluxes induced by the two transmit coils in the receive coil compensate each other.

With the devices described in the related art, however, the sensor must be calibrated before any locating measurement is started. In the calibration procedure, the offset is measured without any external metallic objects present. The deviation from this reference value is subsequently used as an indicator for the presence of metallic objects. This time-consuming calibration process also has the potential for considerable error and damage if a user does not perform it properly.

Based on the detectors described in the related art, the present invention is based on the object of providing a detector of the type described initially, which produces the smallest possible offset signal, and with which the offset is affected as minimally as possible if the coils are placed in the wrong locations.

Another object of the present invention is to provide a method for a detector of this type, which makes it possible to compensate for manufacturing and assembly tolerances in a manner that is cost-effective and as exact as possible.

The object on which the present invention is based is attained with a detector for locating metallic objects having the features of Claim 1, and with a method for operating a detector of this type, according to Claim 15.

### ADVANTAGES OF THE INVENTION

The device—according to the present invention—for locating metallic objects includes at least one transmit coil and at least one receive turn system, which are inductively coupled to one another. The system according to the present invention also includes switching means that make it possible to vary the effective number of turns in the receive turn system.

In contrast to the methods described in the related art, with the detector device according to the present invention, the geometry of the receive turn system, e.g., the receive coils, is modified such that the resultant magnetic total flux through the receive turns disappears if an object to be located is not located near the device.

The principle is based on the fact that one or more additional conductor loops are added to or are removed from the original receive turns. Suitable switching means are provided to implement this variation of the number of receive turns, it being possible to connect or disconnect inductive compensation modules—in related adjustment processes—in the form of conductor loops or portions of such conductor loops. With a suitable design of conductor loops in the receive turns, i.e., one or more receive coils, for example, voltages are induced in these conductor loop portions that exactly offset the fault voltages in the detector, which occur, e.g., due to manufacturing tolerances not having been met.

Compared with adjustment methods that function on the excitation side of the detector, the claimed, circuit-based realization on the receive side is much simpler and cost-effective, since comparatively high-resistance switching means can be used, since very low currents flow in the receive coils as compared with the excitation coils.

The device according to the present invention advantageously makes possible a method for adjusting an inductive measuring device, in particular to operate a locating device, with which the adjustment of a voltage U induced in the receive turns takes place by connecting an adjustment turn system to the turns of the receive turn system. The adjustment turn system can be advantageously composed of one or more compensation modules with turns of a specified length.

In this manner, a measurement device can be adjusted with the device according to the present invention, e.g., at the factory after assembly, thereby enabling optimal operation.

In addition or as an alternative to adjustment at the factory, an adjustment method of this type can also be carried out in a calibration process, which is carried out automatically on a regular basis, or it can be started manually by a user of a related measurement device. To this end, a measurement device can advantageously include a program code that is stored in a related storage medium of the measurement device and controls the method according to the present invention.

Advantageous refinements of the detector described in claim 1 and the adjustment method according to the present invention result with the features of the dependent claims.

Advantageously, the compensation modules, i.e., the current-carrying arc lengths of the adjustment and compensation turns that occur between jumpers, are designed such that it is possible with the inventive adjustment to switch between m different alternative configurations of electrical contacting. In this manner, it is possible to compensate an offset of the detector system caused, e.g., by faulty assembly or unmet manufacturing tolerances, by switching through various combinations of interconnections until an optimal adjustment results.

In advantageous configurations, the adjustment turn system is composed of at least n independent compensation modules KMₙ, each having m(n) different configurations. In these configurations, selective, e.g., stepped switching between the individual configurations m of a compensation module KMₙ is carried out to induce a voltage change ΔU_{n,m} in the receive branch of the compensation sensor, which serves to adjust the sensor. Voltage change ΔU_{n,m} in the receive branch, which results from compensation module KMₙ, differs by a fixed factor from voltage difference ΔU_{n-1,m} of compensation module KMₙ₋₁ with an ordinal number n reduced by one. A system with a factor 2 is particulary advantageous, i.e., binary coding is used for compensation modules KMₙ of the adjustment turn system; the relationship ΔU=(U(n,1)−U(n,2))=2*(U(n−1,1)−U(n−1,2)) therefore applies. A special configuration of the turn lengths of the individual compensation modules of this type results in an optimized, i.e., minimum number of switching means required.

Advantageously, the switching means for the adjustment turn system, i.e., the switching means for varying the effective number of turns in the receive turn system, are located between the turns of a first receive coil and the turns of at least one further receive coil.

In a special embodiment of the inventive detector, the switching means are designed as solder bridges between turns of the receive turn system.

In alternative embodiments, the switching means can also be located such that jumpers result between receive coil turns with a different radius Rₐ or R_{b}.

In a particularly advantageous embodiment of the inventive detector, the switching means are realized using semiconductor elements, e.g., transistors, and field-effect transistors in particular.

In an advantageous embodiment of the inventive detector, two receive coils of the receive turn system are located in a plane. In particular, the coils can be designed with a planar, single-layer turn geometry, to advantageously reduce the capacitance per unit length of the two receive coils in a simple manner.

When a planar geometry of the receive turn system is used, it is possible, in particular, to advantageously realize the receive turn system, e.g., two receive coils, as printed circuit coils on the printed circuit board of a printed circuit, so that no additional costs are incurred in this case to manufacture the receive turns.

In addition, in this advantageous embodiment, the switching means, which are designed, e.g., as semiconductor components, can also be realized directly in a similar manner as a structure of the printed circuit board. For example, several transistors—field effect transistors, in particular—can be provided on the printed circuit board, which perform the task contacting of the coil turns of the two receive coils. By switching between the individual semiconductor switches, it is therefore possible to connect or disconnect compensation modules, so that the effective numbers of turns of the receive turn system are varied. The semiconductor switching elements are switched via control signals to either conduct or block.

In an advantageous embodiment, several receive coils are located coaxially relative to each other and are energized in the opposite directions. The at least one transmit coil can be located in a plane that is parallel—to one receive coil, at least—but is positioned with a height offset.

Advantageously, the at least one transmit coil can be installed on a bobbin, which is attached to a printed circuit board on which the receive turns are formed. In this advantageous configuration, the bobbin of the transmit coil serves as a spacer for the transmit coil above the plane of the receive turns.

The inventive configuration of a detector device for locating metallic objects, which makes it possible to compensate manufacturing and assembly tolerances for the inductive sensor, has the advantage that it functions in a frequency-independent manner. The conductor loops in the receive path, which are connected using suitable switching means, can be manufactured very cost-effectively, particularly when conductor structures on a printed circuit board are used for this purpose. Compared with adjustment methods that function on the excitation side of the detector, the circuit-based realization on the receive side is much simpler and cost-effective, since, e.g., comparatively high-resistance switching means can be used, since very low currents flow in the receive coils as compared with the excitation coils.

In addition, the adjustment described, which is carried out by varying the effective number of turns of the receive turn system, i.e., the receive coils, for example, is practically free of a temperature drift, since its function depends only on the geometry of the magnetic field. It is therefore possible to perform an adjustment over a wide temperature range, which depends little on component tolerances and drift effects.

The inventive detector advantageously enables compensation of manufacturing and assembly tolerances for inductive sensors in a compensation system, which is essentially manufactured without any manual adjustment measures and can therefore be manufactured cost-effectively.

Advantageously, a detector device of this type can be used in an inductive measurement device, e.g., a locating device for detecting metallic objects in walls, ceilings and floors.

In addition, a detector device of this type can be integrated in or on a tool machine, e.g., a drilling tool, to allow the user of this machine to drill reliably. For example, the sensor can be integrated in a drilling or chiseling tool, or it can be designed as a module capable of being connected with a tool of this type. Advantageously, the inventive sensor can be installed in a suction device for dust that is connected to or connectable with the tool machine, and that is used near a wall to be worked on.

Further advantages of the inventive detector result from the description of an exemplary embodiment, below.

### DRAWING

An exemplary embodiment of an inventive detector is depicted in the drawing, and is described in greater detail in the subsequent description. The figures in the drawing, their description and the claims directed to the subject contain numerous features in combination. One skilled in the art will also consider these features individually and combine them to form further reasonable combinations, which are therefore also disclosed in the description.

FIG. 1 shows the basic design of a sensor geometry of a detector for locating metallic objects based on the related art, in a schematic illustration,

FIG. 2 shows an initial exemplary embodiment of the coil assembly of the inventive detector in a simplified, perspective illustration,

FIG. 3 shows a top view of the receive coils of the detector with associated switching means, in a simplified, schematic illustration,

FIG. 4 shows a top view of an alternative exemplary embodiment of the receive coils with associated switching means, in a simplified, schematic illustration.

### DESCRIPTION OF THE EXEMPLARY EMBODIMENTS

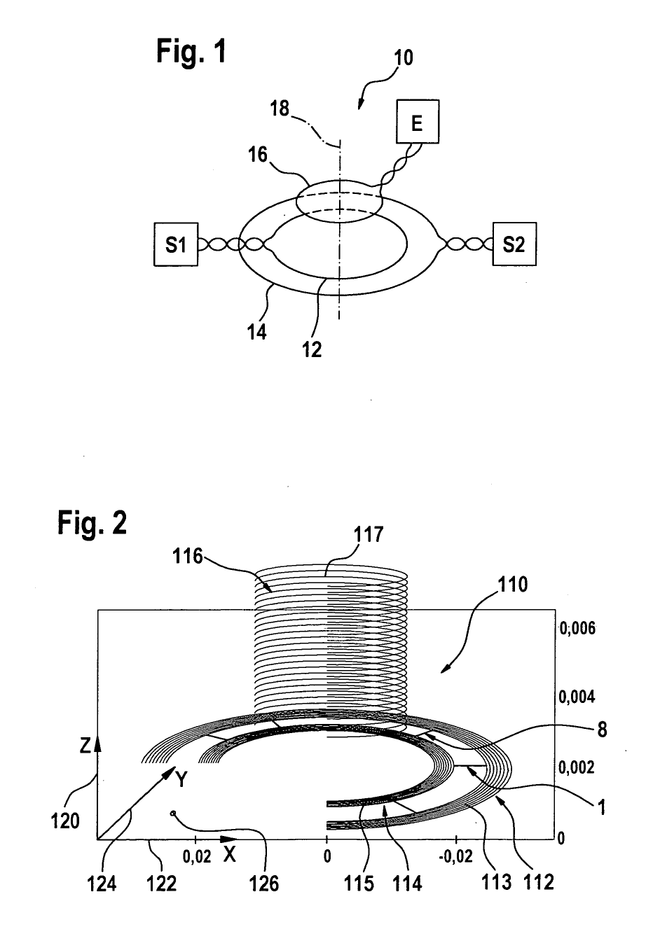

FIG. 1 shows the basic design of an inductive compensation sensor for locating metallic objects, according to the related art. A detector of this type includes three coils in its sensor geometry 10. A first transmit coil 12, which is connected to a first transmitter S1, a second transmit coil 14, which is connected to a second transmitter S2, and a receive coil 16, which is connected to a receiver E. Each coil is depicted as a circular line in this case. The arrangement of these three coils 12, 14, 16 is unique in that they are all located concentrically around a common axis 18. Individual coils 12, 14, 16 have different outer dimensions, so that coil 12 can be inserted in coil 14 coaxially to axis 18.

The two transmit coils 12 and 14 are supplied by their transmitters S1 and S2 with alternating currents with phase opposition. First transmit coil 12 therefore induces a flux in receive coil 16, which is oriented in the opposite direction from the flux induced by second transmit coil 14 in receive coil 16. The two fluxes induced in receive coil 16 compensate each other. As such, receiver E does not detect a receive signal in receive coil 16 if an external, metallic object is not located near coil assembly 10. Flux φ excited by individual transmit coils 12 and 14 in receive coil 16 depends on various variables, e.g., the number of turns and the geometry of coils 12 and 14, and on the amplitude of the currents supplied to the two transmit coils 12 and 14, and on the mutual phase angle of these currents.

With the detectors according to the related art, these variables must ultimately be optimized such that, if a metallic object is not located in receive coil 16, a flux is not induced, or the smallest possible flux φ is induced when current flows through transmit coils 12 and 14. With coil assembly 10 shown in FIG. 1, first transmit coil 12, which is connected to first transmitter S1, and a second transmit coil 14, which is connected to a second transmitter S1, are located coaxially relative to each other in the same plane. Receive coil 16 is located in a plane that is shifted relative to the two transmit coils 12 and 14.

FIG. 2 shows the arrangement of a sensor geometry 10 of the type used in an inventive device for locating metallic objects. Sensor geometry 10 of the detector shown in FIG. 2 includes two receive coils 112 and 114, which are located coaxially relative to each other in plane 126, and which form a receive turn system. A sensor coil 116 is located a certain distance z above this common receive plane 126 of the receive turn system, sensor coil 116 also being located coaxially relative to receive coil 112 and receive coil 114. This assembly is therefore also an inductive compensation sensor.

Receive coils 112 and 114 of the receive turn system have a planar, single-layer turn geometry. A design of receive coils 112, 114 of this type makes it possible to reduce the capacitance per unit length of the two receive coils in a simple manner. It is possible to keep the distance from turn to turn great and, therefore, to keep the parasitic capacitance per unit length of the coil turn small. To insulate the individual copper turns, it is possible, e.g., to not use lacquer, as is typically used, but rather to use suitable other—mainly thicker—insulation means. In particular, paper, cotton and insulation plastics, as used with cables, appear to be suitable. An alternative approach for reducing the parasitic capacitance per unit length is to use multiple-chamber turns for coils 112 and 114.

When a planar geometry is used for the receive turn system, it is also possible, in particular, to realize the two receive coils 112 and 114 as printed circuit coils on the printed circuit board of a printed circuit. In this case, no signficant additional costs are incurred to manufacture the two receive coils. In addition to cost reductions, the configuration of the two receive coils 112 and 114 as printed conductor structures on a printed circuit board has the advantage that the dimensional tolerance of the turns is very low in this case. Technically, it is not a problem to manufacture copper structures exactly on printed circuit boards up to 25 micrometers.

A schematic design of this type is shown in FIG. 2. To enhance clarity, z-axis 120 is stretched relative to x- and y-axes 122 and 124. To elucidate this depiction, numerical values are provided on the particular axes. The numerical values are not absolute values. They merely represent the relative magnitude of the scale of the individual axes in this exemplary embodiment with random units. To further enhance the visibility of the cross sections, one segment of the coils is shown separately in FIG. 2.

The two detector coils 112 and 114 lie in a plane 126, which is intended to symbolize a not-further-shown printed circuit board, and which passes through x-axis 122 and y-axis 124 in FIG. 2. Plane 126 can correspond, e.g., to the top or bottom side of the printed circuit board. Turns 115 of receive coil 114 are wound, e.g., in the clockwise direction, while further outwardly lying turns 113 of receive coil 112 are oriented in the counterclockwise direction. The voltages induced in turns 113, 115 therefore have opposite signs and, provided the dimensioning is suitable, they compensate each other entirely when no external metallic objects are present.

An excitation and/or transmit coil 116 is located above plane 126 of the printed circuit board, i.e., in z-direction 120. It is particularly advantageous when the transmit coil is manufactured on a bobbin, which is then soldered onto printed circuit board 126. Turns 117 of transmit coil 116 are therefore located at a certain, predefined height z above plane 126 of the printed circuit board. Due to the stability required, it is crucial that bobbins be manufactured with wall thicknesses of less than one millimeter. For this reason, the objective is for the distances between the printed circuit board and transmit coil 116 to be at least one millimeter wide.

When the dimensioning of the numbers and radii of turns is suitable, it can be attained that the voltages induced in the two subcoils 112 and 114 of the detector system cancel each other out exactly, if there are no metallic objects located near the detector. This compensation is only successful given a specified, well-defined position of transmit coil 116, however. If the position of transmit coil 116 changes relative to the predefined position, e.g., due to tolerances in coil manufacture or mechanical sensor assembly, a resultant fault voltage UF is induced in receive coils 112 and 114.

According to the present invention, switching means are provided in the claimed detector device, e.g., in the form of semiconductor switches, that make one or more electrical connections possible between individual sections of the turns of different receive coils. In this manner it is possible to also change the effective number of turns of the receive coils subsequently, e.g., after forming and installing the coils, and to therefore adapt them to the actual position of the transmit coil.

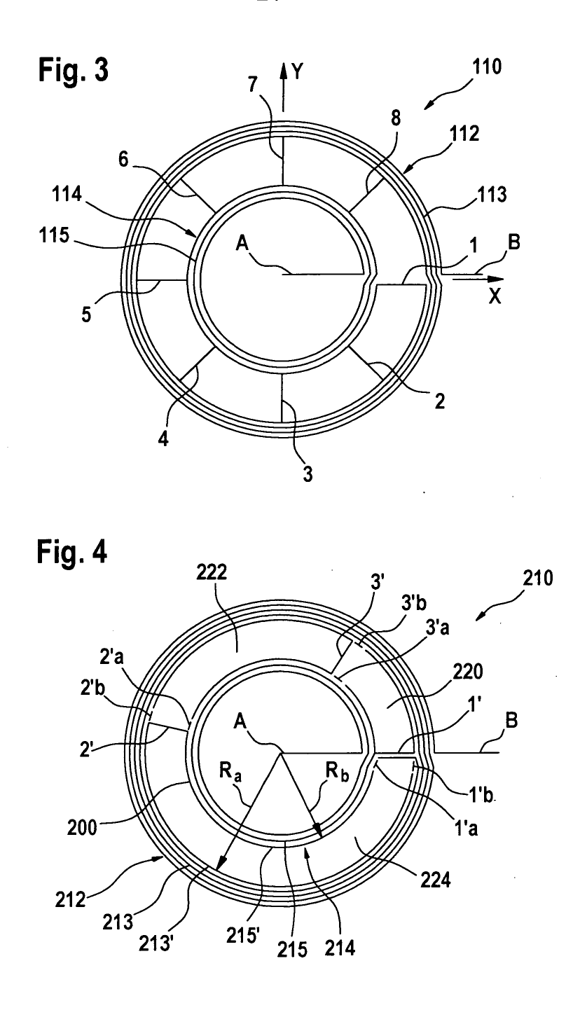

The greatly simplified depiction in FIG. 3 serves to elucidate the mode of operation of the inventive detector. FIG. 3 shows, schematically, the basic arrangement of receive coils with the associated switching means in a top view onto the x,y-plane according to FIG. 2. Transmit coil 116, which is located a certain distance z₀ over the x,y-plane, is therefore not shown in FIG. 3.

The two receive coils 112 and 114 are located in x,y-plane 126. The detection voltage is tapped between the two external connections A and B of the two receive coils 112 and 114 and is processed further in the evaluation circuits of a measuring device assigned to the detector. Turns 115 of receive coil 114 can be electrically connected at various points (1 through 8) with external turns 113 of receive coil 112.

If planar turns 113 or 115 of receive coils 112 or 114 are formed, e.g., as copper structures on a printed circuit board, this contacting can be accomplished using suitable solder bridges, the position of which can be selected as desired. The radii and numbers of turns of the conductor loop system of receive coil 112 or receive coil 114 can be dimensioned, e.g., such that no voltage can be tapped between points A and B when no metallic objects are present, when the transmit coil geometry is ideal and a solder bridge is placed in position 5 in the coil assembly shown in FIG. 3.

If the contacting is carried out, e.g., at point 1, however, a total of three complete turns with a small radius in the clockwise direction (receive turns 115) result between points A and B, and four complete turns with a large radius in the counterclockwise direction result (receive turns 113). If the contacting takes place via a conductive connection at position 5, 2.5 turns are effectively obtained in the clockwise direction, and 3.5 turns are effectively obtained in the counterclockwise direction.

Since the voltages induced in turns 113 of receive coil 112 have a different amplitude and an opposite sign compared to the voltages induced in the conductor loop in receive coil 114, the voltage that can be tapped between points A and B changes depending on the position of the connecting post. By varying the position of the solder bridges, the compensation arrangement of the detector device, which is composed of three coils, can be fine-tuned.

In particular, the effective number of turns of the two energized coils oriented in opposite directions is varied for the receive assembly and is adapted to the particular requirements. Via the subsequent fine-tuning process, for example, a mis-positioning of transmit coil 116—which is not shown in FIG. 3, for reasons described—and an associated fault voltage U_{F} of the inductive sensor resulting from manufacturing tolerances can be eliminated or compensated.

It is feasible, e.g., during production of the inductive detector, to first install the transmit coil with a relatively small positional and dimensional tolerance on the printed circuit board with the receive coils. The result is a slight fault voltage U_{F} when a solder bridge or another switching means that is used is installed or switched in the ideal positions provided for them (position 5 in the example). The position of the solder bridge can now be displaced, e.g., until voltage is no longer measured between points A and B of the receive coils when no metallic objects are present. The incorrect compensation, which is unavoidable due to manufacturing tolerances of coil forms, automatic coilers, and the like, can therefore be advantageously eliminated.

In addition to fixed solder bridges, other connections and, in particular, other switching means are also possible, of course. Solder bridges are a technically less attractive solution, since they make it necessary to use an adjustment process, which is mechanically relatively complex. To realize an adjustment of sensor compensation without an additional manufacturing step, it is possible to also provide several semiconductor elements, e.g., field effect transistors, on the printed circuit board on which the receive coils are formed, the field effect transistors performing the contacting of inner coil system 114 with outer coil system 112. The displacement of the solder bridges is then replaced with a switching between the individual semiconductor switches.

The contact bridges—which would have to be soldered in place manually—can therefore be replaced with a ring of, e.g., transistors, which can be switched via control signals to conduct or block. An adjustment of this type can be carried out in the factory once after the detector is installed in a related measuring device, e.g., a held-held locating device for detecting metallic objects, so that a user is not required to perform complicated calibration measurements before carrying out the measurement itself.

The exact manner in which the fine-tuning of the compensation of a sensor as shown in FIG. 3 can be carried out is determined essentially by the number of switching means provided and/or by the number of connecting bridges (1 . . . 8), and/or by the associated angular pattern, which is defined by these connecting bridges via their subdivision of the arc lengths of the turns of the inductive coils. In the exemplary embodiment in FIG. 3, connections 1 through 8 form a regular 45° pattern around the circumference of the coils, which are circular in this exemplary embodiment. The adjustment or compensation voltage is linearly related to the angle or arc length of the energized turn at which the outer coil 112 is contacted with inner coil 114. If, e.g., the angular pattern shown in FIG. 3 is reduced from 45° to 22.5° by doubling the number of possible positions of jumpers to 16, the compensation voltage can be adjusted with twice the acuity. Basically, any number of jumpers can be used in a system of this type. In fact, the number of jumpers is limited only by practical considerations. An increase in acuity of this type for the compensation or adjustment voltage produced does not create any problems—aside from the relatively complex mechanical realization—when solder bridges are used.

If semiconductor switches such as transistors are used as switching means, practical limits are also placed on the refinement of the adjustment pattern of possible compensation voltages by increasing the number of switches used. In this case, a separate component and an individual control line would have to be provided for every additional contacting angle provided.

FIG. 4 shows an alternative exemplary embodiment 210 of an inventive sensor geometry in a compensation assembly for a detector for locating metallic objects. The compensation assembly and/or adjustment geometry shown in FIG. 4 has the advantage that a substantial reduction in the number of switching means can be realized as compared with the assembly shown in FIG. 3.

With the exemplary embodiment of an inductive compensation sensor according to FIG. 4, the number of turns of receive coil 212 and/or 214 is also varied by connecting available turns or turn branches, thereby resulting in effective numbers of turns for the receive coils. The two coils 212 and 214 are located coaxially relative to each other and are advantageously designed as printed circuit coils on a printed circuit board. The statements made regarding coils 112 and 114 in conjunction with FIG. 3 also apply for the configuration and arrangement of coils 212 and 214.

In deviation from the embodiment shown in FIG. 3, an additional turn 213′—which is oriented in the clockwise direction—was added in the embodiment of an inductive compensation sensor according to FIG. 4 in the inner region of outer coil 212 wound in the counterclockwise direction. That is, an additional turn was added in the inner region of coil 212 that has the same directional orientation as inner receive coil 214. The radius of this additional turn 213′ is labelled Rₐ. This radius is obviously greater than the radius of outer turn 215′ of inner coil system 214, which is referred to below as R_{b}. The voltage induced in a turn with radius R_{b} is greater than the voltage that would be induced in a turn with radius Rₐ, since the distance between the inner turn (R_{b}) and transmit coil 116—which is not shown in FIG. 4 and is positioned with a height offset—is shorter.

Turns 213′ and 215′ with radii Rₐ and R_{b} taken together form an adjustment turn system for the inductive detector, which determines the relative number of turns of the receive coils of the detector. Turns 213′ and 215′ can be subdivided by jumpers 1′, 2′, 3′ or by switching elements 1′a, 1′b or 2′a, 2′b or 3′a, 3′b assigned to the jumpers in conductor elements having different arc lengths, i.e., “compensation modules” (220, 222, 224), thereby resulting in a fine resolution of the number of turns in the adjustment turn system and, therefore, a fine resolution of the compensation voltage inducted in this adjustment turn system. In this manner, the adjustment voltage can be adjusted with great acuity, so that it coincides nearly ideally with the required compensation voltage.

The adjustment principle of the embodiment of an inductive compensation sensor according to FIG. 4 is based, in detail, on the fact that the adjustment turn system for the inductive detector is formed by a connecting line 200, which contacts coil 212 with coil 214. Connecting line 200 is formed as a conductor loop, which is guided to a certain extent on segments of a circle with radius Rₐ, and is formed on the remaining paths by segments of a circle with radius R_{b}. Connecting line 200 is therefore composed of various conductor modules, which are formed out of one or more jumpers 1′, 2′, 3′, and by the compensation modules formed by the jumpers, i.e., the arc lengths—which are current-carrying between these jumpers—of turns 213′ and 215′.

To this end, connecting line 200, which connects coil 212 with coil 214, is subdivided in the exemplary embodiments according to FIG. 4 into 3 compensation modules (220, 222, 224), i.e., 3 subsegments in which the turns have different angular or arc lengths. Advantageously, the measure of their individual angular and arc lengths each differs by a factor of 2 (e.g., 206°+103°+51°=360°). Other gradations of the relative lengths of the compensation modules, i.e., the relative angular arcs of turns with radius Rₐ or R_{b}, are also possible.

With the aid of switching means pairs 1′a, 1′b or 2′a, 2′b or 3′a, 3′b, the individual effective compensation modules (220, 222, 224) can be selected. In this manner, it can be determined whether the current flow in connecting line 200 on the individual angular segments should take place in the inner region (R_{b}) or in the outer region (Rₐ). If, e.g., switches 1′a through 3′a are closed, and switching elements 1′b through 3′b are opened, connecting line 200 is effectively formed by a single turn with radius R_{b}. Due to the open switching elements, the conducting segments with radius Rₐ terminate in a void and are therefore not electrically effective, since they are not contacted.

The voltage induced in connecting line 200 is greater, e.g., for this configuration described above than for a state in which switches 1′a through 3′a are open and switching elements 1′b through 3′b are closed, and the connection of the coils takes place exclusively on outer radius Rₐ.

By selecting a suitable combination of inner and outer segments 215′ and 213′, it is therefore possible to make acute changes to the totality of voltage induced in connecting line 200. The acuity of the adjustment is determined by the length of the smallest angular segment (compensation module), which can be realized using two adjacent jumpers 1′, 2′, 3′.

When FIG. 3 is compared directly with FIG. 4, it is clear that, to attain an adjusting angle of 45° in the exemplary embodiment according to FIG. 3, eight switching elements (1 . . . 8) would be required, while, in the exemplary embodiment shown in FIG. 4, only six switches would be required to attain a comparable adjustment resolution of 51°. A minimum number of switching elements results when the lengths of the angular segments on the compensation turns each differs by a factor of 2. This corresponds to a coding of the lengths of the compensation modules with a base 2 number system.

As an alternative, good solutions are also feasible using, e.g., 3 or 4 different radii, with which 3 or 4 switches per angular segment would be required, and a coding of the adjustment state would be carried out using a base 3 or base 4 number system. Combinations of the state coding are also feasible, with which a different number of alternative switching means are provided in the individual angular segments.

The invention, which has been described only as an example, i.e., in only a few of the possible embodiments, has the advantage that it operates independently of frequency. The conductor loops or segments of conductor loops in the receive path, which are connected using suitable switching means, can be manufactured very cost-effectively, particularly when this only requires conductor structures on a printed circuit board. The switching means can also be formed easily and cost-effectively as semiconductor structures on the same printed circuit board on which the turns of the receive coils are formed. Compared with corresponding adjustment methods that function on the excitation side, the circuit-based realization on the receive side is much simpler and cost-effective, since, e.g., high-resistance switching means can be used, since very low currents flow in the receive coils as compared with the excitation coils.

The inventive detector for locating metallic objects is not limited to the exemplary embodiments shown in the figures.

In particular, the receive turn system of the inventive detector is not limited to the use of two receive coils.

Furthermore, the detector is not limited to the type and number of switching means presented in the exemplary embodiments to vary the effective number of turns of the receive coils. Other codings of the lengths of the compensation modules are also possible.

What is claimed is:

1. A device for locating metallic objects, with at least one transmit coil (116) and at least one receive turn system (112, 114; 212, 214), which are inductively coupled to one another,
wherein
electrical switching means (1, . . . , 8; 1′a, 2′a, 3′a, 1′b, 2′b, 3′b) are provided, which make it possible to vary the effective number of turns of the at least one receive turn system (112, 114; 212, 214).

2. The device as recited in claim 1,
wherein
the effective number of turns of the at least one receive coil (112, 114; 212, 214) is variable by connecting or disconnecting electrical conductor modules.

3. The device as recited in claim 1,
wherein
the switching means (1, . . . , 8; 1′a, 2′a, 3′a, 1′b, 2′b, 3′b) are located between turns (113, 213) of a first receive coil (112, 212) and turns (115, 215) of a second receive coil (114, 214).

4. The device as recited in claim 1,
wherein
jumpers (1′, 2′, 3′) with switching means (1′a, 2′a, 3′a, 1′b, 2′b, 3′b) are located between receive coil turns (213′, 215′) with a different radius Rₐ or R_{b}.

5. The device as recited in claim 1,
wherein
the switching means (1, . . . , 8) or jumpers (1′, 2′, 3′) are realized using solder bridges.

6. The device as recited in claim 1,
wherein
the switching means (1, . . . , 8; 1′a, 2′a, 3′a, 1′b, 2′b, 3′b) are realized using semiconductor components.

7. The device as recited in claim 1,
wherein
at least two receive coils (112, 114; 212, 214) are located coaxially relative to each other.

8. The device as recited in claim 1,
wherein
at least two receive coils (112, 114; 212, 214) are located in a plane.

9. The device as recited in claim 5,
wherein
at least two receive coils (112, 114; 212, 214) are designed as printed circuit coils, particularly on a printed circuit board.

10. The device as recited in claim 6,
wherein
the switching means (1, . . . , 8; 1′a, 2′a, 3′a, 1′b, 2′b, 3′b) are realized using semiconductor switches on the printed circuit board.

11. The device as recited in claim 8,
wherein
at least one transmit coil (116) is located in a plane which is positioned with a height offset and is parallel to at least one receive coil.

12. The device as recited in claim 9,
wherein
at least one transmit coil (116) is installed on a bobbin, which is attached to the printed circuit board.

13. A measuring device, in particular a hand-held locating device, with a device as recited in claim 1.

14. A tool device, in particular a drilling or chiseling tool, with a device as recited in claim 1.

15. A method for operating an inductive compensation sensor (110, 210), with at least one transmit coil (116) and at least one receive turn system (112, 114; 212, 214), with which the adjustment of a voltage U induced in a receive coil (112, 114; 212, 214) takes place by connecting an adjustment turn system (113, 115; 213′, 215′) to the turns (113, 115; 213, 215) of the receive turn system (112, 114; 212, 214), this adjustment turn system (113, 115; 213′, 215′) including one or more compensation modules (220, 222, 224).

16. The method as recited in claim 15, with which, for each compensation module (220, 222, 224), it is possible to switch between m different alternative configurations (1′a, 2′a, 3′a, 1′b, 2′b, 3′b) of the electrical contacting.

17. The method as recited in claim 15,
wherein
the adjustment turn system (113, 115; 213′, 215′) is composed of at least n (n=1 . . . N) independent compensation modules KMₙ (220, 222, 224), each having m(n) (m(n)=1 . . . M(n)) different configurations, in which a voltage change ΔU_{n,m} is induced, with ΔU=(U(n,m)−U(n,m+1)), in the receiving branch (212, 214) of the compensation sensor (210) by selectively switching between individual configurations m of a compensation module KMₙ (220, 222, 224).

18. The method as recited in claim 17,
wherein
the compensation modules KMₙ (220, 222, 224) are configured such that the voltage change ΔU_{n,m} differs from the voltage difference ΔU_{n-1,m,} with ΔU_{n-1,m}=(U(n−1,m′)−U(n−1,m′+1)), of compensation module KMₙ₋₁ by the factor M(n−1), with an ordinal number n reduced by one.

19. The method as recited in claim 17,
wherein
binary coding with M(n)=2 is used for the compensation modules KMₙ (220, 222, 224) of the adjustment turn system (113, 115; 213′, 215′), so that the relationship ΔU=(U(n,1)−U(n,2))=2*(U(n−1,1)−U(n−1,2)) applies.
